(19) United States
(12) Patent Application Publication
(10) Pub. No.: US 2026/0240056 A1
(43) Pub. Date: Aug. 13, 2026

(54) SEMICONDUCTOR BONDING SURFACE WITH MULTIPLE PASSIVATION MATERIALS

(71) Applicant: Micron Technology, Inc., Boise, ID (US)

(72) Inventors: Brandon P. Wirz, Boise, ID (US); Andrew M. Bayless, Boise, ID (US); Jeremy E. Minnich, Boise, ID (US); Owen R. Fay, Meridian, ID (US)

(21) Appl. No.: 19/451,564

(22) Filed: Jan. 16, 2026

Related U.S. Application Data
(60) Provisional application No. 63/755,960, filed on Feb. 7, 2025.

(51) Int. Cl. H10W 90/00; H10W 74/01; H10W 74/10; H10W 74/43; H10W 74/47; H10W 80/00; H10W 90/26

(52) U.S. Cl. CPC H10W 90/792; H10W 74/01; H10W 74/137; H10W 74/43; H10W 74/476; H10W 80/327; H10W 90/26

(57) ABSTRACT

A semiconductor device having a bonding surface with multiple passivation materials is disclosed. The semiconductor device includes a semiconductor substrate. A first passivation material and a second passivation material are disposed at a side of the first semiconductor substrate to implement a bonding surface. The second passivation material is different from the first passivation material. The first passivation material is exposed at a first portion of the bonding surface and the second passivation material is exposed at a second portion of the bonding surface.

### CROSS-REFERENCE TO RELATED APPLICATION(S)

The present application claims priority to U.S. Provisional Patent Application No. 63/755,960, filed Feb. 7, 2025, the disclosure of which is incorporated herein by reference in its entirety.

### TECHNICAL FIELD

The present disclosure generally relates to semiconductor device assemblies and more particularly relates to a semiconductor bonding surface with multiple passivation materials.

### BACKGROUND

Wafer bonding is a wafer-level packaging technology that can be used to form semiconductor device assemblies. Wafer bonding is often performed using a bonding chuck capable of contacting two semiconductor wafers in a controlled manner. During wafer bonding, the two semiconductor wafers can be brought into contact with one another at their respective bonding surfaces. The bonding surfaces can include conductive pads coupled with circuitry at each of the respective wafers and passivation material surrounding the conductive pads. Once contacting, the conductive pads on each of the two semiconductor wafers can bond to form interconnects between the wafers. Similarly, the passivation material at each respective wafer can bond to mechanically couple the two semiconductor wafers.

### BRIEF DESCRIPTION OF THE DRAWINGS

FIG. 1 illustrates a simplified schematic partial plan view of a semiconductor device in accordance with an embodiment of the present technology.

FIG. 2 illustrates a simplified schematic partial plan view of a semiconductor device in accordance with an embodiment of the present technology.

FIGS. 3-7 illustrate simplified schematic cross-sectional views of a series of steps for creating a semiconductor device in accordance with an embodiment of the present technology.

FIG. 8 illustrates a schematic view of a system that includes a semiconductor device configured in accordance with an embodiment of the present technology.

### DETAILED DESCRIPTION

Semiconductor devices are integrated in many devices to implement memory cells, processor circuits, imager devices, and other functional elements. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. One such technique is to implement stacked semiconductor devices with multiple semiconductor dies assembled in a vertical stack. Interconnects can be created between the semiconductor dies to enable signals to be communicated between the dies.

Stacked semiconductor devices can be created through direct bonding (e.g., fusion or hybrid bonding). For example, wafer-wafer bonding can be performed by placing two semiconductor wafers in close proximity and contacting the wafers at their center. Once the wafers contact, the wafers can bond to one another. The wafers can bond to one another in accordance with a bond wave, which propagates out from the initial contacting site to bring portions of the wafers together. As the bond wave propagates from the centers of the wafers to the edges, the bonding surfaces of the wafers can become misaligned. This misalignment can cause a portion of a bonding surface of a first wafer to bond with a non-analogous portion of a bonding surface of a second wafer, which can create voids along a bonding interface between the first and second wafers. The voids can occur when portions of the bonding surfaces of the wafers are not bonded. These voids can decrease the strength of the bond between the wafers or increase the stress in the wafers, which can decrease the mechanical strength of the semiconductor devices. Moreover, the misalignment of the wafers can cause interconnects between the wafers to become misaligned, which can cause the semiconductor devices fabricated from the wafers to become inoperable or perform unreliably.

Voids and other misalignments are more likely to occur when the bond wave propagates quickly. For example, the faster bond wave can cause some areas to experience insufficient pressure or contact, leading to incomplete bonding and the formation of voids. The occurrence of voids and other misalignments become even more prevalent when the bond wave propagates in a non-uniform fashion (e.g., different portions of the bond wave propagate across different portions of the wafer at different speeds instead of as a uniform and radially expanding front). Many such bond waves naturally propagate in such a non-uniform manner, however. For example, many bond waves propagate in a diamond or other non-uniform pattern. In such cases, uneven distribution of bonding forces across the wafer surfaces can cause the occurrence of voids, as certain areas may experience insufficient pressure or contact, leading to incomplete bonding and the formation of voids.

Moreover, an increase in voids and other misalignments can occur at the periphery of the semiconductor wafers due to the Joule-Thomson effect, which causes air and other compositions pushed toward the edge of the wafer to condense at the wafer edge. For example, sudden pressure drop can occur at the wafer edge, which can cause supersaturation of the water and other condensates, resulting in nucleation of liquid droplets at the edge of the wafer. These droplets can create voids at the wafer edge. This problem only worsens as the bond wave speed or non-uniformity is increased. Accordingly, techniques are needed to ensure a slower or more uniform bond wave.

To address these needs and others, the present technology relates to implementing a bonding surface with multiple passivation materials. The different passivation materials can have properties that allow a bond wave to propagate at different speeds. Thus, the passivation materials can be used to alter the speed at which a bond wave propagates across different portions of the bonding surface. For example, the propagation of a bond wave across a bonding surface made from a single passivation material can be predicted. Then, based on this predicted bonding wave, a second passivation material can be placed in particular locations to adjust the propagation of a bonding wave across these locations. For example, the second passivation material can be used to slow the bonding waves at locations where the bonding wave propagates faster than at other locations. In doing so, the uniformity of the bonding wave can be improved.

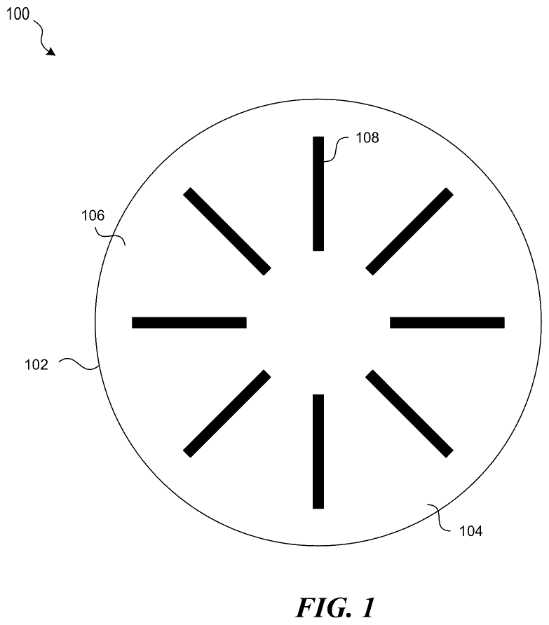

FIG. 1 illustrates a simplified schematic plan view of a semiconductor device 100 that includes a semiconductor substrate 102 with a bonding surface 104 implemented using multiple passivation materials. The semiconductor device 100 is implemented on the semiconductor substrate 102. The substrate 102 is illustrated as a wafer-level substrate on which multiple semiconductor dies can be disposed. It should be appreciated, however, that the semiconductor substrate 102 could instead be any other substrate, such as a die-level substrate. Accordingly, the semiconductor device 100 could instead be a single semiconductor die rather than multiple semiconductor dies. Thus, a similar bonding surface 104 can be implemented on a square, rectangular, or other semiconductor die. Moreover, the semiconductor device 100 can be bonded with another semiconductor device through wafer-wafer, chip-wafer, or any other bonding type.

The semiconductor device 100 can be bonded with an additional semiconductor device at the bonding surface 104 (e.g., through fusion or hybrid bonding). The bonding surface 104 can be implemented using multiple passivation materials to configure the propagation of the bonding wave. Specifically, a first passivation material 106 and a second passivation material 108 are exposed at the bonding surface 104. The first passivation material 106 and the second passivation material 108 can have different material properties that increase or decrease the speed of the bonding wave. For example, passivation materials with higher surface energies, higher bond densities, lower contact angles, or lower surface roughness may increase the speed at which the bond wave propagates across these materials. On the other hand, passivation materials with lower surface energies, lower bond densities, higher contact angles, or higher surface roughness may decrease the speed at which the bond wave propagates across these materials.

The first passivation material 106 and the second passivation material 108 can be placed at specific locations to adjust the speed of the bond wave at these locations. In aspects, the locations at which the speed of the bond wave is to be changed can be determined based on a prediction of the propagation of the bond wave (e.g., based on computer modeling or previous observations of bond waves). Passivation that slows the bond wave can then be placed at locations where the bond wave propagates quickly, or passivation that speeds up the bond wave can be placed at locations where the bond wave propagates slowly. In some regards, a slower bond wave will result in improved consistency and decrease the occurrence of voids. Accordingly, it may be desirable to maintain uniformity through slowing of the bond wave in various locations.

Although any number of configurations of the first passivation material 106 and the second passivation material 108 are possible based on the desired alteration of the bond wave, FIG. 1 illustrates a particular configuration that may be useful for slowing a bond wave that propagates in a diamond pattern, which may occur with some regularity. For example, the second passivation material 108 can be placed in radially extending lines between the center of the bonding surface 104 and a perimeter of the bonding surface 104. The second passivation material 108 can propagate the bond wave slower than the first passivation material 106. Thus, the radially extending lines of the second passivation material 108 can slow the fast-propagating corners of the diamond-shaped bond wave. The second passivation material 108 can extend any portion of the radial line between the center (or a point approximately corresponding to the center (e.g., a point within 1, 5, or 10 percent of the length, width, or radius of the bonding surface from the center)) and perimeter of the bonding surface 104. Thus, the second passivation material 108 need not extend continuously from the center (or near the center) of the bonding surface 104 to the perimeter of the bonding surface 104. In aspects, the second passivation material 108 can be disposed in any number of lines (e.g., 2, 4, 6, 8, 10, 12, and so on). In some cases, the lines of the second passivation material 108 will be equally spaced along the circumference of the perimeter of the bonding surface 104 to slow the corners of the diamond-shaped bond wave.

Similarly, the first passivation material 106 can be exposed on the bonding surface 104 outside the locations where the second passivation material 108 is exposed. The first passivation material 106 can be a same passivation material that was used to predict the propagation of the bond wave (e.g., without the slowing from the second passivation material 108). Alternatively, the first passivation material 106 can be a passivation material that facilitates a faster propagation of the bond wave (e.g., to increase the contrast in wave speed with the second passivation material 108) or a slower propagation of the bond wave (e.g., to slow the speed of the bond wave overall). Moreover, although illustrated as only using two different passivation materials, the bonding surface 104 could instead implement any number of passivation materials (e.g., 3, 4, 5, 6, and so on) to further fine-tune the propagation of the bond wave.

Any number of passivation materials can be used to implement the first passivation material 106 and the second passivation material 108 (or any other number of passivation materials used to implement the bonding surface 104). For example, the first passivation material 106 or the second passivation material 108 can include silicon oxide (SiO), silicon nitride (SiN), silicon oxide carbon (SiOC), silicon carbide (SiC), silicon carbon nitride (SiCN), silicon oxynitride (SiON), tetraethyl orthosilicate (TEOS), or a High Aspect Ratio Process (HARP) dielectric, and so on. While material properties can be adjusted to provide different or facilitate different speeds of bond wave propagation, in some cases, oxides, such as SiO, SiOC, SiON, and others, can facilitate relatively fast bond wave propagation. Alternatively, HARP dielectric can facilitate relatively slow bond wave propagation. TEOS and SiCN can provide a moderate bond wave speed. Accordingly, these materials may be selected for the bonding surface 104 based on these properties. As a specific example, the first passivation material can be a material that facilitates a fast or moderate bond wave speed, while the second passivation material can be a material that facilitates a slow or moderate bond wave speed.

Additional operations can be performed on the first passivation material 106 or the second passivation material 108 to alter its material properties and control the propagation of the bond wave. For example, the surface of the first passivation material 106 or second passivation material 108 can be smoothed or roughened to speed or slow the bond wave, respectively. Alternatively or additionally, the first passivation material 106 or the second passivation material 108 can be exposed to a plasma (e.g., a nitrogen plasma or argon plasma) to alter the surface properties. These operations can be performed on the entire bonding surface 104, to the first passivation material 106 or the second passivation material 108 individually, or in accordance with any other pattern to tailor the propagation of the bond wave. For example, the second passivation material 108 can be roughened to further slow the bond wave or the first passivation material 106 can be smoothed to speed the bond wave.

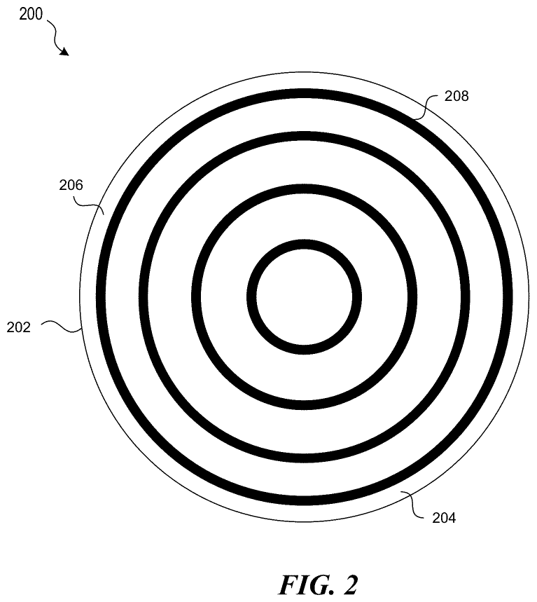

FIG. 2 illustrates a simplified schematic plan view of a semiconductor device 200 that includes a semiconductor substrate 202 with a bonding surface 204 implemented using multiple passivation materials. The semiconductor device 200 illustrates one of a number of alternate configurations of passivation material 206 and passivation material 208 used to implement the bonding surface 204. In aspects, the passivation material 208 can facilitate slower propagation of the bond wave than the passivation material 206. As illustrated, the passivation material 208 is implemented as multiple ellipses (e.g., circles) exposed at the bonding surface. The passivation material 208 can be implemented as any number of ellipses (e.g., 1, 2, 3, 4, 5, and so on). The ellipses can be centered about a point approximately corresponding to the center of the bonding surface 204 (e.g., within 1, 5, 10, or any number therebetween percent of the length, width, or diameter of the bonding surface 204). The ellipses can be centered about the same point or different points. The ellipses can be of the same or different thicknesses. In aspects, by implementing the passivation material 208 as ellipses, the propagation of the bond wave can be kept more uniformly radial.

Although not illustrated as such, passivation material 208 can sometimes be implemented near the perimeter of the bonding surface 204 (e.g., within 1, 5, 10, or any number therebetween of the length, width, or diameter of the bonding surface 204). In this way, the bond wave can be slowed near the edge of the bonding surface 204 to reduce the occurrence of voids and other inconsistencies resulting from the Joule-Thomson effect.

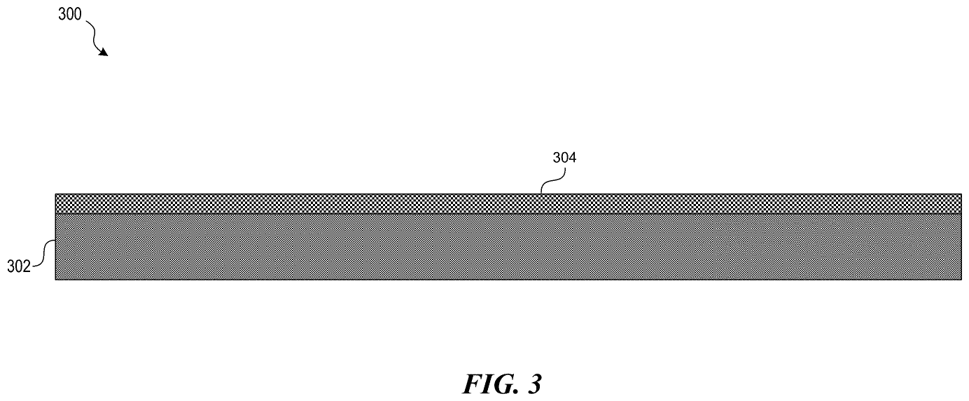

FIGS. 3-7 illustrate simple schematic cross-sectional views of multiple semiconductor devices being bonded with one another and further assembled. The illustrations of FIGS. 3-7 will illustrate the semiconductors being bonded at the wafer level. Semiconductor devices could similarly be bonded at the chip level. Although illustrated in a particular configuration, one or more operations illustrated in FIGS. 3-7 may be omitted, repeated, or reorganized. Additionally, other operations not illustrated in FIGS. 3-7 could be added to the operations illustrated in FIGS. 3-7 to create similar semiconductor devices.

Beginning with FIG. 3, a simplified schematic cross-sectional view of a semiconductor device 300 is illustrated. The semiconductor device 300 is implemented on a semiconductor substrate 302. The semiconductor substrate 302 can be a wafer-level substrate, a chip-level substrate, or any other substrate. In this way, the semiconductor substrate 302 can be used to implement a single semiconductor die or multiple semiconductor dies. The semiconductor substrate 302 can be formed from any semiconductive material, such as silicon, germanium, silicon-germanium alloy, gallium arsenide, gallium nitride, etc. In some cases, the substrate 302 is a semiconductor wafer. In other cases, the substrate 302 may be a silicon-on-insulator (SOI) substrate, such as silicon-on-glass (SOG) or silicon-on-sapphire (SOP), or epitaxial layers of semiconductor materials on another substrate. The conductivity of the substrate 302, or sub-regions of the substrate, may be controlled through doping using various chemical species including, but not limited to, phosphorous, boron, or arsenic. Doping may be performed during the initial formation or growth of the substrate, by ion-implantation, or by any other doping means. Electrical components can then be implemented on the substrate 302 (e.g., to implement one or more semiconductor dies).

A passivation material 304 can be disposed at the substrate 302 to insulate the electronic components and provide a bonding surface for stacking additional semiconductor devices. The passivation material 304 can include SiO, SiN, SiOC, SiC, SiCN, SiON, TEOS, a HARP dielectric, or any other passivation material. In some cases, the passivation material 304 can be a passivation material that propagates the bond wave faster than a later to be deposited passivation material. In some cases, the passivation material 304 can be the same as used to make the prediction of the propagation of a bond wave that is used to determine the optimal pattern for the later to be deposited passivation material. As illustrated, the passivation material 304 can be disposed across the entire first side of substrate 302. Portions of the passivation material 304 can then be removed to provide spaces for the later to be deposited passivation material. Alternatively, the passivation material can be selectively deposited in only locations where the passivation material 304 will not be deposited (e.g., rather than in a single uniform layer). Thus, the passivation material 304 can form at a portion of the final bonding surface. The passivation material 304 can be deposited through any appropriate method, for example, chemical vapor deposition, physical vapor deposition, plating, electroless plating, spin coating, and/or other suitable techniques.

Although not illustrated, one or more contact pads can be exposed through the passivation material 304 to form interconnects with additional dies. The contact pads can be coupled with functional circuitry implemented on the substrate 302 (e.g., transistors, diodes, traces, lines, vias, TSVs, and so on) to provide connectivity thereto. The contact pads can be formed from any conductive material, for example, copper.

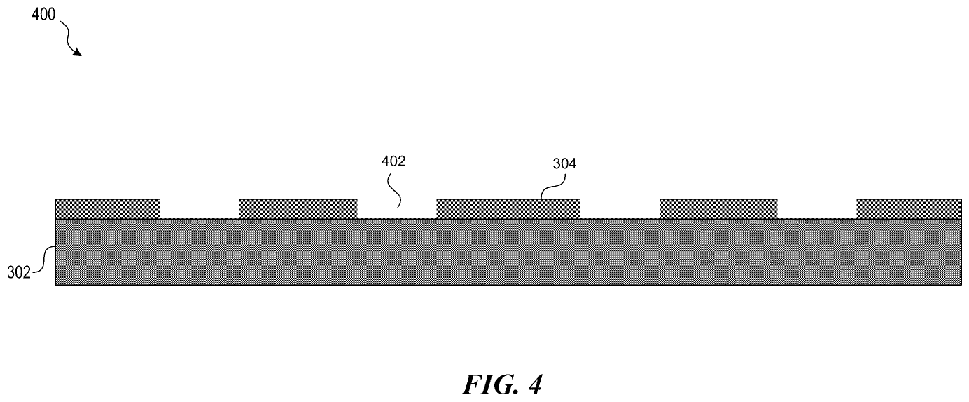

Turning now to FIG. 4, a semiconductor device 400 is illustrated. The semiconductor device 400 includes one or more recessions 402 in the passivation material 304. The recessions 402 can be formed, for example, using plasma etching, wet etching, chemical-mechanical planarization (CMP), or other suitable techniques. In some cases, the recessions 402 can be formed through laser etching or a point-of-use plasma to reduce the complexity of the process. In other cases, the recessions 402 can be formed using a photomask.

The recessions 402 can have a depth that extends to the surface of the substrate 302 or any electronic components disposed thereon. Alternatively, the recessions 402 can extend only a portion of the way into the passivation layer (e.g., the passivation material 304) such that a position of the passivation layer is still present at the bottom of the recessions 402. The recessions 402 can be formed at location that corresponds to where the later to be deposited passivation material is to be exposed at the bonding surface. Thus, the recessions 402 can create any pattern for altering the bond wave as discussed above. For example, the recessions 402 can be made to form radially extending lines, ellipses, or any other pattern.

In some cases, the pattern for the recessions 402 (and the later to be deposited passivation material) can be determined from prediction of the propagation of a bond wave across the passivation material 304. For example, locations where the bond wave is expected to propagate more quickly (e.g., corners of the diamond-shaped bond wave propagation) can be replaced with the later to be deposited passivation material after recessions 402 are formed at these locations. Alternatively or additionally, the recessions 402 can be elliptical (e.g., circular) to keep the propagation of the bond wave more radial in response to a prediction that the bond wave will not propagate radially. The prediction of the bond wave can be performed physically or analytically. The prediction can be specific to the passivation material 304, the later to be deposited passivation material, a different passivation material, or generic to any passivation material.

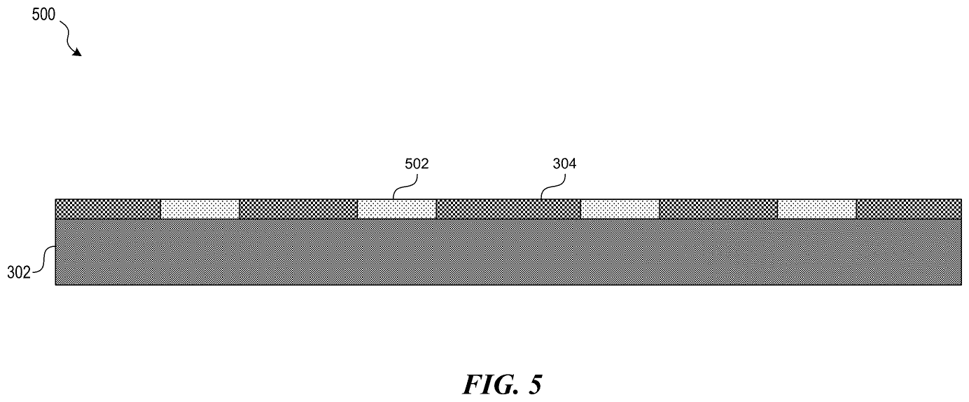

Turning to FIG. 5, a semiconductor device 500 is illustrated. The semiconductor device 500 includes a passivation material 502. The passivation material 502 can be deposited in the recessions formed in FIG. 4. In some cases, the passivation material 502 can be deposited directly in the recessions such that the passivation material 502 and the passivation material 304 are flush at the bonding surface. In other cases, the passivation material 502 can be disposed in the recessions and over at least a portion of the passivation material 304. A portion of the passivation material can then be removed (e.g., through CMP) to expose the passivation material 304.

The passivation material 502 can be any passivation material. For example, the passivation material 502 can include SiO, SiN, SiOC, SiC, SiCN, SiON, TEOS, a HARP dielectric, or any other passivation material. In some cases, the passivation material 502 may be a passivation material across which the bond wave propagates slower than across the passivation material 304. For example, the passivation material 502 can include a passivation material that is slow or moderate, such as SiCN, TEOS, or HARP.

Alternatively, the recessions can be formed in the negative space of the pattern implemented at the bonding surface. In this way, the newly added passivation material (e.g., the passivation material to slow the bond wave at particular locations) can be deposited first. The recessions can then be formed in this passivation material at locations where this material is not intended to be deposited. The recessions can then be filled with a second passivation material.

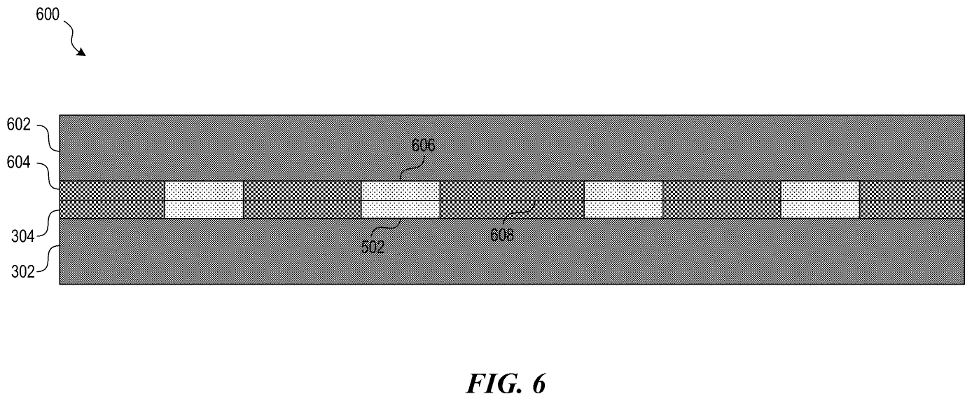

Turning to FIG. 6, a semiconductor device 600 is illustrated. The semiconductor device includes the substrate 302 coupled with an additional substrate 602. The additional substrate 602 can be a die-level substrate or wafer-level substrate (e.g., implementing multiple semiconductor dies). The additional substrate 602 includes passivation material 604 (e.g., of same kind as the passivation material 304) and passivation material 606 (e.g., of same kind as the passivation material 502). The passivation material 604 and the passivation material 606 can be disposed at locations that correspond to the locations of the passivation material 304 and the passivation material 502, respectively. In this way, when the substrate 302 and the substrate 602 are bonded, the passivation material 604 and the passivation material 606 can contact the passivation material 304 and the passivation material 502, respectively. In doing so, the bond wave can be further controlled.

Alternatively, a single passivation material (e.g., the same as or different from the passivation material 304 or the passivation material 502) can be disposed across the entire substrate. In this case, the bond wave can be controlled by the pattern of passivation materials on the substrate 302. In yet other aspects, multiple passivation materials can be disposed but in a different pattern from the pattern disposed on the substrate 602. In these embodiments, the bond wave can be controlled through a combination of the passivation materials on the substrate 302 and the passivation materials on the substrate 602.

The substrate 302 can be bonded with the substrate 602 through direct bonding (e.g., fusion bonding or hybrid bonding) at the bond line 608. The bond line 608 can be a contacting point between a bonding surface of the substrate 302 implemented by the passivation material 304 and the passivation material 502 and a bonding surface of the substrate 602 implemented by the passivation material 604 and the passivation material 606. The bonding can be performed through steps of contacting the substrate 302 and the substrate 602 at their bonding surface and allowing the bond wave to propagate outward toward the edge.

The bond wave can be controlled not only with alterations to the particular passivation materials exposed at the bond line 608 but also through steps to alter the material properties at the bond line 608. For example, fusion bonding or hybrid bonding can include a step of exposing the bonding surface to a plasma (e.g., a hydrogen, nitrogen, or argon plasma) to activate the bonding surface. This plasma activation can cause the bonding wave to propagate more quickly or more slowly across the bonding surfaces. Thus, plasma activation across the bonding surfaces or at particular locations of the one or more of the bonding surfaces can be used to control the propagation of the bond wave. In some cases, only one of the passivation materials (e.g., passivation material 304 or passivation material 502) can be plasma-activated while the other is not.

The propagation of the bond wave can be similarly altered by changing the surface roughness of one or more of the bonding surfaces. For example, a rougher bonding surface may decrease the speed at which the bond wave propagates across the bonding surface. The surface roughness could be altered mechanically by sanding, scrubbing with steel wool, wire brushing, sandblasting, iceblasting, plasma treating, or laser texturing the bonding surface. Alternatively or additionally, the surface roughness could be altered chemically through chemical etching or plasma treatments. In some cases, the surface roughness can be altered across the entire bonding surface. In other cases, the surface roughness can be altered only at particular locations, for example, at the passivation material 502 but not the passivation material 304.

In general, the bond wave can be controlled by changing the surface properties. For example, the contact angle of the bonding surface, the extent to which the surface is hydrophilic or hydrophobic, the surface roughness of the bonding surface, the passivation material at the bonding surface, the bond density at the bonding surface, or the surface energy of the bonding surface can alter the speed at which a bond wave propagates across the surface. Accordingly, any number of alterations can be made to the surface to modify the propagation of the bonding wave to create a slowly propagating, uniform bond wave. For example, where the bonding wave is desired to be slowed, the contact angle can be increased, the surface can be made more hydrophobic, the bonding density can be decreased, the surface roughness can be increased, or the bonding energy can be decreased. Where the bond wave is desired to be sped up, the surface can be altered in the opposite ways.

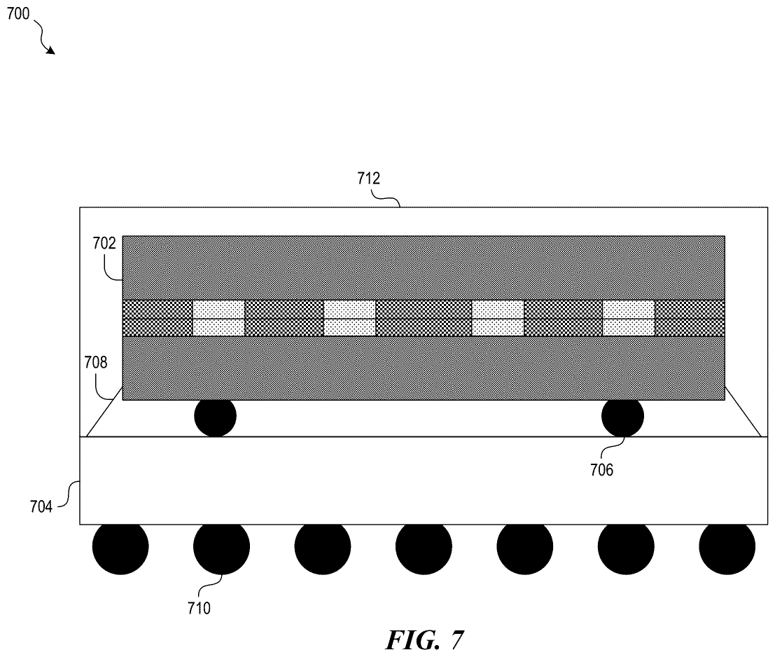

The bonded substrates can then be singulated into individual semiconductor devices. For example, when the substrate 302 or the substrate 602 are wafer-level substrates, these substrates can be singulated to separate the individual devices thereon. The semiconductor device 600 can include 4, 8, 12, 30, 50, 100, or any other number of semiconductor die stacks. Similarly, although only two iterations of substrate stacking are illustrated, additional substrates can be stacked onto the semiconductor device 100 by repeating the operations described above. Accordingly, the total number of substrates in the stack can equal 2, 3, 4, 5, 6, 8, 10, 12, 14, 16, or any other number of substrates. In aspects, the semiconductor device 600 can include a high-bandwidth memory (HBM) device compliant with one or more HBM standards (e.g., HBM, HBM2, HBM3, and so on). In yet other aspects, each semiconductor device 600 can include a logic die (e.g., a central processing unit (CPU), graphics processing unit (GPU), processor, and so on) with multiple stacks of semiconductor dies (e.g., memory dies) mounted thereon at different lateral locations. Once singulated, the individual semiconductor devices can be packaged, as illustrated in FIG. 7.

FIG. 7 illustrates a simplified schematic cross-sectional view of a semiconductor device 700, where a stack of semiconductor dies 702 is packaged into a semiconductor device. The stack of semiconductor dies 702 can include the semiconductor dies bonded in FIG. 6. A base die of the stack of semiconductor dies 702 can be coupled with a package-level substrate 704 (e.g., printed circuit board (PCB), interposer, etc.). Connective structures 706 (e.g., solder balls, solder bumps, conductive pillars, etc.) may be disposed between contact pads (not shown) at the base die and contact pads (not shown) at a top side of the package-level substrate 704 to implement interconnects that electrically couple the stack of semiconductor dies 702 and the package-level substrate 704.

An underfill material 708 (e.g., capillary underfill) can be provided between the stack of semiconductor dies 702 and the package-level substrate 704 to provide electrical insulation to the connective structures 706 and structurally support the assembly. The package-level substrate 704 can include internal routing circuity (e.g., traces, lines, vias, and other connective structures) that connects the contact pads at the top surface to contact pads (not shown) at the bottom side. Connective structures 710 can be disposed at the contact pads at the bottom side to provide external connectivity to other devices (e.g., on a motherboard).

The semiconductor device 700 may include multiple passivation materials at the bond line between the semiconductor dies 702. Moreover, the bond between the semiconductor dies 702 may have a lesser number of voids due to the control of the bond wave such that it propagates slowly and uniformly during bonding. Thus, the semiconductor dies 702 may be bonded more robustly, resulting in increased yield. The semiconductor device 700 can further include an encapsulant material 712 (e.g., mold resin compound or the like) that at least partially encapsulates the semiconductor dies 702 and the package-level substrate 704 to prevent electrical contact therewith and provide mechanical strength and protection to the assembly.

Although in the foregoing example embodiment semiconductor device assemblies have been illustrated and described as including a particular configuration of semiconductor dies, in other embodiments assemblies can be provided with different configurations of semiconductor dies. For example, the semiconductor device assemblies illustrated in any of the foregoing examples could be implemented with, for example, a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.) or a mix of logic and memory dies (e.g., a memory controller die and a memory die controlled thereby).

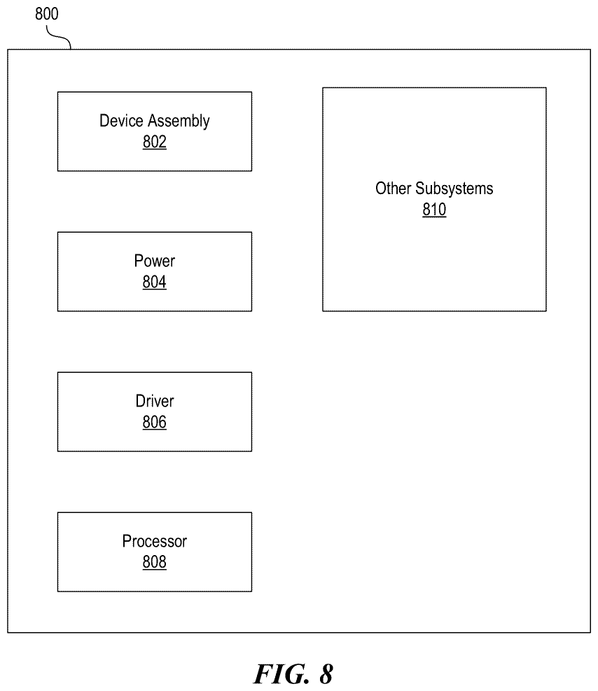

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly 802 (e.g., a discrete semiconductor device), a power source 804, a driver 806, a processor 808, and/or other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances, and other products. Components of the system 800 may be housed in a single unit or distributed over multiple, interconnected units (e.g., through a communications network). The components of the system 800 can also include remote devices and any of a wide variety of computer-readable media.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a SOI substrate, such as SOG or SOP, or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a semiconductor substrate; and
a first passivation material and a second passivation material different from the first passivation material disposed at a side of the semiconductor substrate to implement a bonding surface,
wherein the first passivation material is exposed at a first portion of the bonding surface and the second passivation material is exposed at a second portion of the bonding surface.

2. The semiconductor device of claim 1, wherein the second portion of the bonding surface corresponds to portions of one or more lines extending substantially radially along a line between a point approximately corresponding to a center of the bonding surface and a perimeter of the bonding surface.

3. The semiconductor device of claim 1, wherein the second portion of the bonding surface corresponds to one or more ellipses centered about a point approximately corresponding to a center of the bonding surface.

4. The semiconductor device of claim 1, wherein the second portion of the bonding surface corresponds to a portion proximate to a perimeter of the bonding surface.

5. The semiconductor device of claim 1, wherein the first passivation material has a higher surface energy than the second passivation material.

6. The semiconductor device of claim 1, wherein:
the first passivation material comprises a first one of:
tetraethyl orthosilicate (TEOS), High Aspect Ratio Process (HARP) dielectric, silicon oxide (SiO), silicon oxide carbon (SiOC), and silicon carbon nitride (SiCN); and
the second passivation material comprises a second one of:
TEOS, HARP dielectric, SiO, SiOC, and SiCN.

7. The semiconductor device of claim 1, wherein the first passivation material has a greater bond density than the second passivation material.

8. The semiconductor device of claim 1, wherein the first passivation material has a lower contact angle than the second passivation material.

9. The semiconductor device of claim 1, wherein:
the first passivation material is exposed to a first plasma; and
the second passivation material is exposed to a second plasma different from the first plasma.

10. A method for assembling a semiconductor device, comprising:
providing a first semiconductor substrate;
disposing a first passivation material at a side of the first semiconductor substrate such that at least a portion of the first passivation material is exposed at a first portion of a bonding surface;
disposing a second passivation material different from the first passivation material at the side of the first semiconductor substrate such that at least a portion of the second passivation material is exposed at a second portion of the bonding surface; and
coupling a second semiconductor substrate with the first semiconductor substrate at the bonding surface through the first passivation material and the second passivation material.

11. The method of claim 10, further comprising:
predicting a propagation of a bond wave used to couple the first semiconductor substrate and the second semiconductor substrate; and
disposing the second passivation material such that it is exposed at locations on the bonding surface at which the bond wave is predicted to propagate faster than at other locations on the bonding surface.

12. The method of claim 10, further comprising:
removing at least a portion of the first passivation material; and
disposing the second passivation material at least at locations that correspond to the portion of the first passivation material that has been removed.

13. The method of claim 12, wherein the first passivation material is removed using a photomask.

14. The method of claim 12, wherein the first passivation material is removed using point-of-use plasma etching.

15. The method of claim 12, wherein the first passivation material is removed using laser etching.

16. The method of claim 10, wherein:
the first passivation material comprises a first one of:
tetraethyl orthosilicate (TEOS), High Aspect Ratio Process (HARP) dielectric, silicon oxide (SiO), silicon oxide carbon (SiOC), and silicon carbon nitride (SiCN); and
the second passivation material comprises a second one of:
TEOS, HARP dielectric, SiO, SiOC, and SiCN.

17. The method of claim 10, further comprising:
exposing the first passivation material to a first plasma; and
exposing the second passivation material to a second plasma different from the first plasma.

18. A semiconductor device assembly, comprising:
a first semiconductor substrate;
a first passivation material and a second passivation material different from the first passivation material disposed at a side of the first semiconductor substrate,
wherein the first passivation material and the second passivation material form a first bonding surface,
wherein the first passivation material is exposed at a first portion of the first bonding surface and the second passivation material is exposed at a second portion of the first bonding surface; and
a second semiconductor substrate coupled with the first semiconductor substrate at the first bonding surface.

19. The semiconductor device assembly of claim 18, further comprising:
a third passivation material and a fourth passivation material disposed at a side of the second semiconductor substrate,
wherein the third passivation material is a same material as the first passivation material,
wherein the fourth passivation material is a same material as the second passivation material,
wherein the third passivation material and the fourth passivation material form a second bonding surface,
wherein the third passivation material is exposed at a third portion of the second bonding surface and the fourth passivation material is exposed at a fourth portion of the second bonding surface, and
wherein the second semiconductor substrate couples with the first semiconductor substrate at the first bonding surface and the second bonding surface such that the first portion and third portion of the first bonding surface aligns with the third portion and fourth portion of the second bonding surface, respectively.

20. The semiconductor device assembly of claim 18, wherein the first semiconductor substrate is a wafer-level substrate.
